(19) United States
(12) Patent Application Publication
(10) Pub. No.: US 2025/0132161 A1
(43) Pub. Date: Apr. 24, 2025

(54) ANGLED GATE CUT REGION

(71) Applicant: INTERNATIONAL BUSINESS MACHINES CORPORATION, ARMONK, NY (US)

(72) Inventors: Min Gyu Sung, Latham, NY (US); Juntao Li, Cohoes, NY (US); Ruilong Xie, Niskayuna, NY (US); Julien Frougier, Albany, NY (US); Chanro Park, Clifton Park, NY (US)

(21) Appl. No.: 18/490,298

(22) Filed: Oct. 19, 2023

(51) Int. Cl. H01L 21/28; H01L 21/8238; H01L 27/092; H01L 29/06; H01L 29/417; H01L 29/423; H01L 29/66; H01L 29/775

(52) U.S. Cl. CPC H01L 21/28123; H10D 30/014; H10D 30/43; H10D 30/6729; H10D 30/6735; H10D 62/121; H10D 84/0172; H10D 84/038; H10D 84/85

(57) ABSTRACT

A semiconductor integrated circuit (IC) device that includes an angled gate cut region, a first transistor associated with a first gate, and a second transistor associated with a second gate. The angled gate cut region may be angled such that its top surface area is nearest a boundary of the first transistor and its bottom surface area is nearest a boundary of the second transistor. The angled gate cut region may separate the first gate from the second gate and may further separate the source/drain regions of the first transistor from the source/drain regions of the second transistor. The angled gate cut region may provide for adequate frontside surface area of the first gate to which a frontside gate contact may connect and may further provide for adequate backside surface area of the second gate to which a backside gate contact may connect.

### BACKGROUND

The embodiments of the present disclosure relate to fabrication methods and resulting structures for semiconductor devices.

A backside back-end-of-line (BEOL) network, such as a backside power distribution network (BSPDN) may include signal wires for signal routing and power wires for providing power potential (e.g., VDD, VSS, etc.). The backside BEOL network may allow for the distribution of power wires and signal wires between both the frontside and backside of the semiconductor IC device. The backside BEOL network may further allow for the full or partial decoupling of signal routing and/or power routing and/or allows dividing or splitting power wires and/or signal wires between both the frontside and backside of the semiconductor IC device. By incorporating the backside BEOL network, routing congestion may be reduced, which may lead to further semiconductor IC device scaling. For example, semiconductor IC devices that incorporate a backside BEOL network can result in a 30% area reduction and improved current-resistance (IR) drop compared to typical semiconductor IC devices that include solely a frontside BEOL network.

However, the backside BEOL network may be difficult to manufacture as it requires multi-layer components to connect the backside wires with active devices included in the semiconductor IC device. Particularly, there are fabrication difficulties in connecting a backside contact to a backside of a gate or other electrode.

### SUMMARY

In an embodiment of the present disclosure, a semiconductor integrated circuit (IC) device is presented. The semiconductor IC device includes a first transistor that includes a first gate and a second transistor that includes a second gate. The second gate includes a backside gate extension. The semiconductor IC device further includes an angled gate cut region that separates the first gate from the second gate, a frontside gate contact connected to the first gate, and a backside gate contact that is connected to backside gate extension. The angled gate cut region may therefore separate the first gate from the second gate. The angled gate cut region may further provide for reducing or shrinking the pitch or distance between an associated boundary of the first transistor and an associated boundary of the second transistor while also providing for adequate frontside or backside surface area of the first gate and second gate, respectively, to land or join a gate contact therewith.

In an example, the first transistor further includes a first pair of source/drain (S/D) regions, the second transistor further comprises a second pair of S/D regions, and the angled gate cut region separates the first pair of S/D regions from the second pair of S/D regions. In this manner, the angled gate cut region may extend beyond the sidewalls of the first gate and second gate and further separates the first pair of S/D regions from the second pair of S/D regions.

In an example, the semiconductor IC device further includes a frontside back end of line (BEOL) network connected to the frontside gate contact and a backside BEOL network connected to the backside gate contact. By associating the first gate and the second gate with both the frontside BEOL network and the backside BEOL network, the presented semiconductor IC device may be further scaled (i.e., shrunk in size) and/or may have reduced signal and/or power wiring routing complexities therein.

In an example, one of the first pair of S/D regions is connected to the frontside BEOL network by a frontside S/D contact and the other of the first pair of S/D regions is connected to the backside BEOL network by a backside S/D contact. By associating the S/D regions with both the frontside BEOL network and the backside BEOL network, the presented semiconductor IC device may be further scaled and/or may have reduced signal and/or power wiring routing complexities therein.

In an example, the semiconductor IC device further includes a shallow trench isolation (STI) region underneath and between the first transistor and the second transistor. The STI region may adequately physically and or electrically separate and/or isolate the first transistor from the second transistor.

In an example, the backside gate extension region extends through the STI region. As such, the gate extension region may be located below and between the first transistor and the second transistor and may provide power wiring and/or signal wiring access to the second gate from backside or underneath the second gate.

In an example, a bottom surface of the angled gate cut region is substantially coplanar with a top surface of the STI region. In this manner, an angled gate cut region opening may land on the STI region such that the STI region forms the well or bottom portion of the angled gate cut region opening and may result in the bottom surface of the angled gate cut region being coplanar with the top surface of the STI region.

In an example, the frontside gate contact, the backside gate contact, and the gate extension region are located between a boundary of the first transistor and a boundary of the second transistor. As a result, power wiring and/or signal wiring access to the first gate and to the second gate may be provided in the same general section near the angled gate cut region between the first transistor and the second transistor.

In an example, the frontside gate contact is a vertical interconnect access (VIA) contact within the frontside BEOL network, and the backside gate contact is a VIA contact within the backside BEOL network. By associating the first gate and the second gate with both the frontside BEOL network and the backside BEOL network, the presented semiconductor IC device may be further scaled and/or may have reduced signal and/or power wiring routing complexities therein.

In another embodiment, a semiconductor integrated circuit (IC) device is presented. The semiconductor IC device includes a first transistor that is associated with a first active region and that includes a first gate. The semiconductor IC device further includes a second transistor that is associated with a second active region and includes a second gate. The semiconductor IC device further includes an angled gate cut region between the first active region and the second active region that separates the first gate from the second gate. The angled gate cut region may therefore separate the first gate from the second gate. The angled gate cut region may further provide for reducing or shrinking the pitch or distance between the first active region and the second active region while also providing for adequate frontside or backside surface area of the first gate and second gate, respectively, to land or join a gate contact therewith.

In an example, a top surface area of the angled gate cut region is located closer to the first active region relative to the second active region, and a bottom surface area of the angled gate cut region is located closer to the second active region relative to the first active region. This relative angle of the angled gate cut region may further provide for the adequate frontside or backside surface area of the first gate and second gate, respectively, to land or join a gate contact therewith.

In an example, the semiconductor IC device may further include a backside gate contact that is connected to a backside of the first gate and a frontside gate contact connected to a frontside of the second gate. The angled gate cut region may further provide for adequate frontside or backside surface area of the first gate and second gate, respectively, to land or join the frontside gate contact and the backside gate contact thereto, respectively.

In an example, the first transistor further comprises a first pair of source/drain (S/D) regions, the second transistor further comprises a second pair of S/D regions, and the angled gate cut region further separates the first pair of S/D regions from the second pair of S/D regions. In this manner, the angled gate cut region may extend beyond the sidewalls of the first gate and second gate and further separates the first pair of S/D regions from the second pair of S/D regions.

In an example, the semiconductor IC device may further include a frontside back end of line (BEOL) network connected to the frontside gate contact and a backside BEOL network connected to the backside gate contact. By associating the first gate and the second gate with either the frontside BEOL network or the backside BEOL network, the presented semiconductor IC device may be further scaled and/or may have reduced signal and/or power wiring routing complexities therein.

In an example, one of the first pair of S/D regions is connected to the frontside BEOL network by a frontside S/D contact and the other of the first pair of S/D regions is connected to the backside BEOL network by a backside S/D contact. By associating the S/D regions with both the frontside BEOL network and the backside BEOL network, the presented semiconductor IC device may be further scaled and/or may have reduced signal and/or power wiring routing complexities therein.

In an example, the semiconductor IC device further includes a shallow trench isolation (STI) region between the first active region and the second active region and underneath the angled gate cut region. As such, the gate extension region may be located below and between the first transistor and the second transistor and may provide power wiring and/or signal wiring access to the second gate from backside or underneath the second gate.

In an example, a bottom surface of the angled gate cut region is substantially coplanar with a top surface of the STI region. In this manner, an angled gate cut region opening may land on the STI region such that the STI region forms the well or bottom portion of the angled gate cut region opening and may result in the bottom surface of the angled gate cut region being coplanar with the top surface of the STI region.

In an example, the frontside gate contact and the backside gate contact are located between the first active region and the second active region. As a result, power wiring and/or signal wiring access to the first gate and to the second gate may be provided in the same general section near the angled gate cut region between the first active region and the second active region.

In an example, the frontside gate contact is a vertical interconnect access (VIA) contact within a frontside back end of line (BEOL) network, and the backside gate contact is a VIA contact within a backside BEOL network. By associating the first gate and the second gate with both the frontside BEOL network and the backside BEOL network, the presented semiconductor IC device may be further scaled and/or may have reduced signal and/or power wiring routing complexities therein.

In yet another embodiment, a semiconductor integrated circuit (IC) device method is presented. The method includes forming a gate structure upon and around first channels of a first transistor and upon and around second channels of a second transistor. The method includes forming an angled gate cut region opening within the gate structure separating the gate structure into a first gate upon and around the first channels of the first transistor and a second gate upon and around the second channels of the second transistor. The method further includes forming an angled gate cut region by depositing dielectric material within the angled gate cut region opening.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 and FIG. 2 depict a semiconductor IC device that includes an angled gate cut region that may separate and be located between a first gate and a second gate and/or that may be between a first source/drain (S/D) and a second S/D region, according to one or more embodiments of the disclosure.

FIG. 3 through FIG. 15 depict various fabrication structure views of an exemplary semiconductor IC device that includes an angled gate cut region, according to one or more embodiments of the disclosure.

FIG. 16 depicts a method of fabricating a semiconductor IC device that includes a angled gate cut region, according to one or more embodiments of the disclosure.

### DETAILED DESCRIPTION

The present disclosure relates to fabrication methods and resulting semiconductor integrated circuit (IC) devices that include an angled gate cut region. In some examples, the angled gate cut region may provide adequate geometrical separation of a first gate and a second gate for placement of a frontside gate contact and a backside gate contact thereagainst, respectively.

The embodiments of the present disclosure recognize the potential benefits of semiconductor IC device fabrication techniques that allow for a frontside contact to connect against a frontside of a first gate or other electrode and that allow for a backside contact to connect against a backside of a second gate or other electrode. To achieve these and potential other benefits, a semiconductor IC device is presented that includes an angled gate cut region. The angled gate cut region may separate and be located between a first gate and a second gate. The angled gate cut region may geometrically separate the first and second gate in a manner that provides for a frontside contact to be connected against a frontside of the first gate and a backside contact to be juxtaposed against a backside of the second gate.

A gate may be a component or structure of a transistor. A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some transistors, integration of the transistors with a backside back-end-of-line (BEOL) network is one of the key challenges to providing increasing packaged IC device densities and performance increases. By incorporating a backside BEOL network into the semiconductor IC device, routing congestion may be eased. Currently, there is a need for semiconductor IC device fabrication techniques that allow for both a frontside contact to connect against a frontside of a first gate and a backside contact to connect against a backside of a second gate.

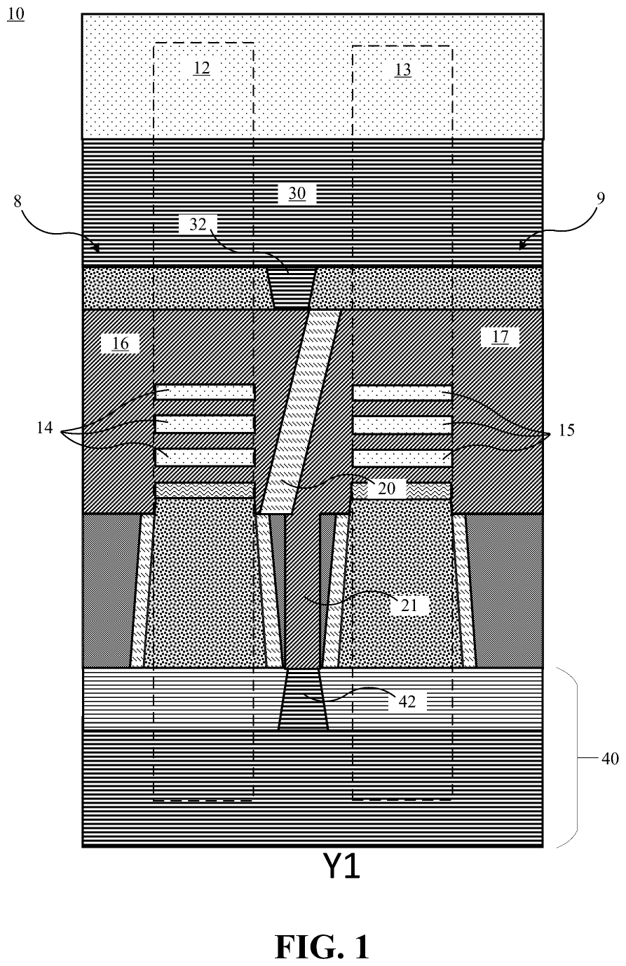

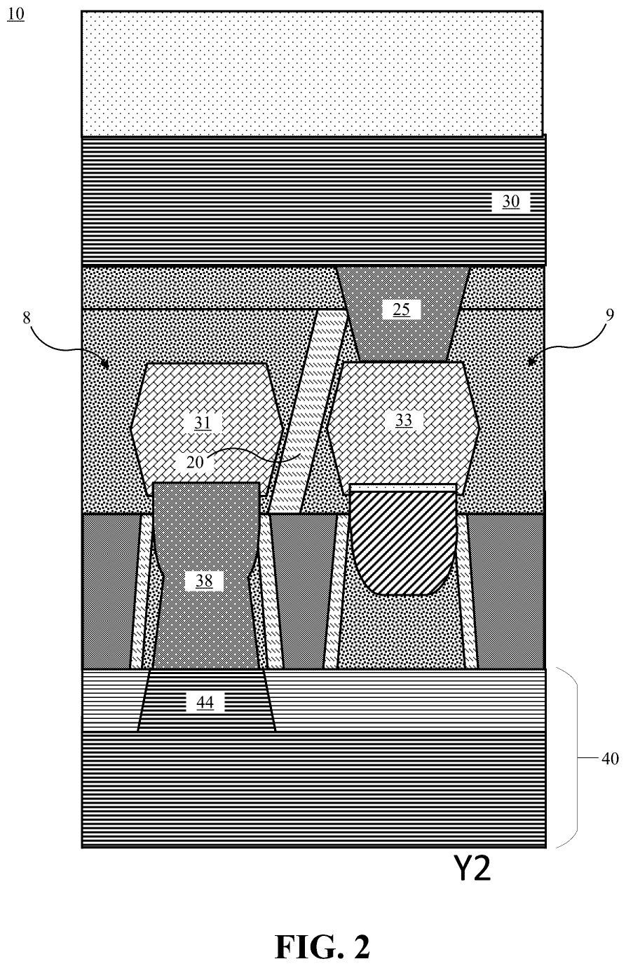

Referring now to FIG. 1 and to FIG. 2, in which an illustrative semiconductor integrated circuit (IC) device 10 that includes an angled gate cut region 20 is depicted. Semiconductor IC device 10 may further include a first transistor 8 and a second transistor 9. Transistor 8 may include a first gate 16 that is around and that contacts each of a first series of vertically stacked channels 14 and may further include source/drain regions 31 that are connected to respective end surfaces of the first series of vertically stacked channels 14. Similarly, transistor 9 may include a second gate 17 that is around and that contacts each of a second series of vertically stacked channels 15 and may further include source/drain regions 33 that are connected to respective end surfaces of the second series of vertically stacked channels 15.

According to one or more embodiments, the angled gate cut region 20 may separate the first gate 16 from the second gate 17. For example, the angled gate cut region 20 may be located between and adequately electrically isolate the first gate 16 from the second gate 17. Similarly, the angled gate cut region 20 may separate at least one of the S/D regions 31 from at least one of the S/D regions 33.

The first series of vertically stacked channels 14 may be included in a first active region 12. In some implementations, a channel width of the first series of vertically stacked channels 14 may define the width of the first active region 12. Similarly, the second series of vertically stacked channels 15 may be included in a second active region 13, in which the channel width of the second series of vertically stacked channels 15 may define the width of the second active region 13. In some embodiments of the disclosure, and as depicted, the angled gate cut region 20 may be located between the first active region 12 and the second active region 13.

The first gate 16 may include a frontside in which a frontside contact 32 is joined thereto. The frontside contact 32 may be a middle-of-line (MOL) type contact that connects the first gate 16 with a frontside back-end-of-line (BEOL) network 30 or alternatively may be an interconnect within a lowest level of the frontside BEOL network 30. In some embodiments of the disclosure, and as depicted, the frontside contact 32 may be located between the first active region 12 and the second active region 13.

The second gate 17 may include a backside from which a backside gate extension 21 protrudes. In some embodiments of the disclosure, and as depicted, the backside gate extension 21 may be located between the first active region 12 and the second active region 13. For example, the backside gate extension 21 may extend through a shallow trench isolation (STI) region that is located between the first active region 12 and the second active region 13. A backside contact 42 may be joined to the backside gate extension 21. The backside contact 42 may be a MOL type contact that connects the backside gate extension 21 to a backside BEOL network 40 or alternatively may be an interconnect within a lowest level of the backside BEOL network 40.

The frontside BEOL network 30 may be connected to one or more of the S/D regions 33 by a frontside contact 25. As depicted, the frontside contact 25 may be a MOL type contact that connects the one or more of the S/D regions 33 with the frontside BEOL network 30. The backside BEOL network 40 may be connected to one or more of the S/D regions 31 by a backside contact 38. As depicted, the backside contact 38 may be a MOL type contact. In other implementations, the frontside contact 25 may be an interconnect within a lowest level of the frontside BEOL network 30 and the backside contact 38 may be an interconnect within a lowest level of the backside BEOL network 40.

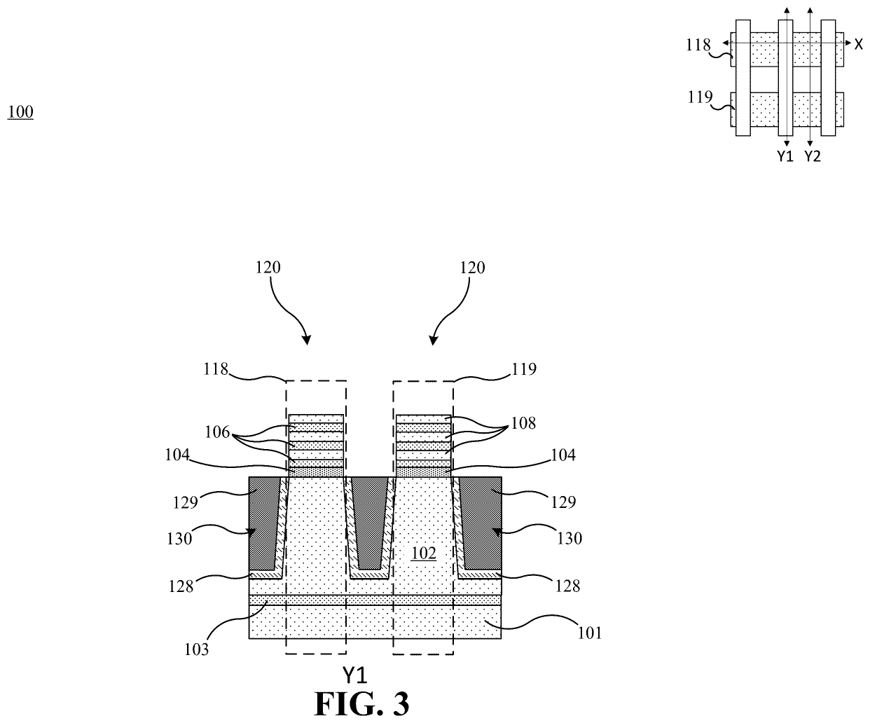

For clarity, the first active region 12 and the second active region 13 are illustrative boundaries for the first transistor 8 and the second transistor 9, respectively. In some embodiments, the first transistor 8 may be a p-type transistor and the second transistor 9 may be an n-type transistor, or vice versa. Between these adjacent boundaries may be a median region, which may be defined by the underlying STI region 130 (shown in FIG. 3) that is between the first and second series of vertically stacked channels 14, 15 and associated S/D regions 31, 33. This median region may include the frontside contact 32, the angled gate cut region 20, the backside gate extension 21, and the backside contact 42 therewithin.

The semiconductor IC structure 10 may be fabricated by semiconductor IC device fabrication techniques that allow for the frontside contact 32 to connect against a frontside of the first gate 16 and that allow for the backside contact 42 to connect against a backside of a second gate 17 (e.g., by way of backside gate extension 21, or the like). To achieve these and potential other benefits, the semiconductor IC device 10 includes the angled gate cut region 20 that may allow for adequate first gate 16 frontside area to which the frontside contact 32 may contact and that may allow for adequate second gate 16 backside area to which the backside contact 42 may contact.

FIG. 3 depicts a cross-sectional view of a semiconductor IC device 100 that is to include an angled gate cut region after initial fabrication operations, in accordance with embodiments of the present disclosure. In these initial fabrication stages, nanolayers are formed upon a substrate structure, the nanolayers are patterned into nanolayer stacks, and shallow trench isolation (STI) regions are formed.

For clarity, FIG. 3 also depicts a partial top-down view of the semiconductor IC device 100 that includes respective locations of cross-sectional plane X, cross-sectional plane Y1, and cross-sectional plane Y2. For example, cross-sectional plane X is a vertical plane across active region 118 and adjacent gates, cross-sectional plane Y1 is a vertical plane across a gate, active region 118, and active region 119, and cross-sectional plane Y2 is a vertical plane across active region 118 and active region 119 between adjacent gates. Cross-sectional plane X is typically orthogonal to cross-sectional planes Y1, Y2. Cross-sectional planes Y1 and Y2 are typically parallel.

The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any other suitable material(s) than those listed above, and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101, and the upper substrate 102 may be composed of Si and may be epitaxially grown from the top surface of etch stop layer 103.

Nanolayers may be formed over the substrate structure by forming a bottom sacrificial nanolayer 104 and by forming a series of alternating sacrificial nanolayers 106 and active nanolayers 108 thereupon. In certain examples, the bottom sacrificial nanolayer 104 is initially formed directly on an upper surface of the substrate structure. In other examples, certain layer(s) may be formed between the upper surface of the substrate structure and the bottom sacrificial nanolayer 104. In an example, the bottom sacrificial nanolayer 104 may be formed by epitaxially growing a SiGe layer with high Ge %, ranging from 50% to 70%. The bottom sacrificial nanolayer 104 may have etch selectivity relative to the sacrificial nanolayers 106 and active nanolayers 108.

The nanolayers may be further formed by fabricating the alternating series of sacrificial nanolayers 106, such as SiGe sacrificial nanolayers, and active nanolayers 108, such as Si nanolayers, upon the bottom sacrificial nanolayer 104. The sacrificial nanolayers 106 can have Ge % ranging from 20% to 45%. In an implementation, the alternating sacrificial nanolayers may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In the illustrated semiconductor IC device 100, there are a total of three sacrificial nanolayers 106 and three active nanolayers 108. However, it should be appreciated that any suitable number of alternating nanolayers may be formed. Although it is specifically contemplated that the bottom sacrificial nanolayer 104 and the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottom sacrificial nanolayer 104, the sacrificial nanolayers 106, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between vertically adjacent active nanolayers 108) may range from 5 nm to 15 nm. However, the VSP must be of a sufficient value to accommodate the formation of a gate that is to be be formed in the spaces created by later removal of respective portions of the sacrificial nanolayers 106.

Further, in the depicted fabrication stages, the nanolayers may be patterned into nanolayer stacks 120 and shallow trench isolation (STI) regions 130 may be formed.

To form one or more nanolayer stacks 120, a mask layer (not shown) may be formed on the uppermost nanolayer. The mask layer may be comprised of any suitable mask material(s). The mask layer may be patterned and used to perform the nanolayer stack 120 patterning process. In the nanolayer stack 120 patterning process, any suitable material removal process (e.g., reactive ion etching or RIE) may be used to remove portions of the alternating nanolayers down to the level of the substrate structure, or the like. Following the nanolayer stack 120 patterning process, one or more nanolayer stacks 120 are formed. Subsequently, the mask layer may be removed. A horizontal width of a first nanolayer stack 120 may define a width of a first active region 118 and a horizontal width of a second nanolayer stack 120 may define a width of a second active region 119.

The removal of undesired portion(s) of the alternating nanolayers may further remove undesired portions of substrate structure that are adjacent to respective footprints of nanolayer stacks 120 to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer stacks 120 may utilize the etch stop layer 103 to stop the etch and form the bottom well of the one or more STI region openings.

A STI region 130 may be formed upon and/or within the substrate structure within respective STI region openings. The STI regions 130 may be formed by depositing electrical dielectric material(s) within respective STI region opening(s) that are adjacent to the one or more nanolayer stacks 120. A top surface of the one or more STI regions 130 may be coplanar with a top surface of the substrate structure. The one or more STI regions 130 may have a volume and/or geometry that sufficiently electrically isolates components or features of neighboring transistors, or the like, may sufficiently electrically isolate neighboring nanolayer stacks 120, and/or may sufficiently electrically isolate neighboring active regions 118, 119. For clarity, a particular STI region 130 may separate and adequately electrically isolate neighboring active regions 118, 119.

In an example, the STI region(s) 130 may be formed by depositing a STI liner 128 within the STI region openings. Subsequently, STI region(s) 130 may be further formed by depositing STI dielectric material 129 upon the STI liner 128. An etch back, recess, or the like, may occur to remove undesired or over formed STI liner 128 and/or STI dielectric material 129, such that the top surface of the STI region(s) 130 is/are coplanar with a bottom surface of the bottom sacrificial nanolayer 104. STI liner 128 may be composed of but not limited to a nitride, low-K nitride (i.e., a nitride material with a lower dielectric constant relative to SiO₂), or the like. The STI dielectric material 129 may be composed of but not limited to an oxide, low-K oxide (i.e., an oxide material with a lower dielectric constant relative to SiO₂), or the like. For clarity, as the STI regions 130 are formed within the substrate structure upon which the microdevices may be formed, the STI regions 130 may generally be located below or underneath the microdevices.

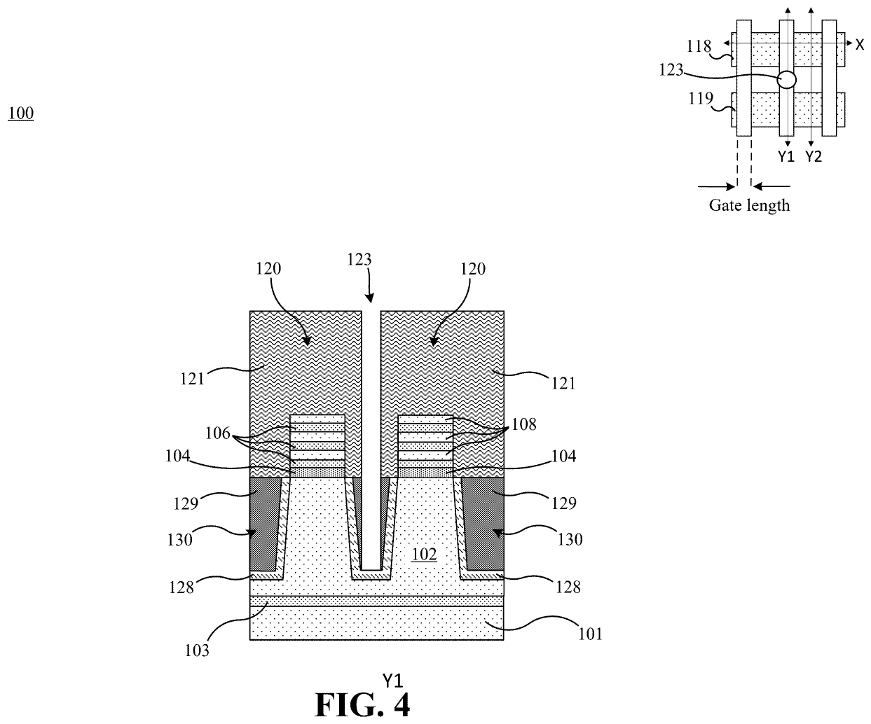

FIG. 4 depicts cross-sectional views of the semiconductor IC device 100 after fabrication operations, in accordance with embodiments of the present disclosure. In the depicted fabrication stages, a gate extension mask 121 may be formed upon STI regions 130 and upon and around the one or more nanolayer stacks 120 and a gate extension opening 123 may be formed.

The gate extension mask 121 may be deposited upon STI regions 130 and upon and around the one or more nanolayer stacks 120 and may be comprised of any suitable mask material(s), such as an organic planarization layer (OPL), or the like. The gate extension mask 121 may be patterned and used to perform the gate extension opening 123 patterning process. In the gate extension opening 123 patterning process, any suitable material removal process (e.g., reactive ion etching or RIE) may be used to remove portions of an STI region 130 that may be located in line with a particular gate structure that is to be formed and may further be located between active region 118 and active region 119. For example, applicable region(s) of STI dielectric material 129 of STI region 130 may be removed to form gate extension opening 123. In this example, an associated portion of STI liner 128 may be exposed by and may form the well of the gate extension opening 123. As depicted in the top-down view of FIG. 4 the gate extension opening 123 may have a geometry with an appropriate dimension that is larger than a predetermined gate length of the gate structure that is to be formed. In other words, applicable sidewalls, of the to be formed gate structure, that define its gate with may be inset relative to the gate extension that is to be formed within the gate extension opening 123.

The etch that may form the gate extension opening 123 may be timed or otherwise controlled to stop the removal of the STI region 130 such that the depth or bottom of the one or more gate extension opening 123 has a predetermined or desired depth dimension. For example, the depth or bottom of the one or more gate extension opening 123 may utilize the STI liner 128 as an etch stop. Subsequently, gate extension mask 121 may be removed by a substrative removal technique, such as an etch, OPL ash or the like.

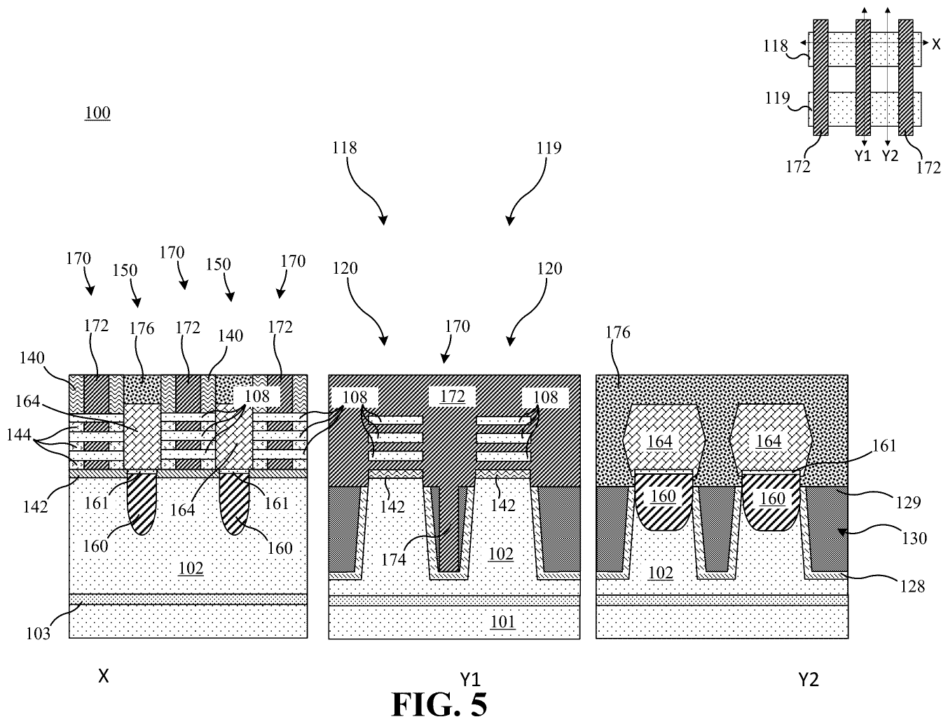

FIG. 5 depicts cross-sectional views of the semiconductor IC device 100 after fabrication operations, in accordance with embodiments of the present disclosure. In the depicted fabrication stages, one or more sacrificial gate structures (not shown) may be formed. Further in the depicted fabrication stages, the bottom sacrificial nanolayer may be removed, gate spacers 140 may be formed, and bottom dielectric isolation region(s) may be formed. Further in the depicted fabrication stages, source/drain (S/D) recesses may be formed within the one or more nanolayer stacks between the gate spacers of neighboring sacrificial gate structures. Further in the depicted fabrication stages, the sacrificial nanolayers may be indented and a respective inner spacer may be formed within respective indents. Further in the depicted fabrication stages, one or more backside contact placeholders may be formed. Further in the depicted fabrication stages, S/D regions may be formed. Further in the depicted fabrication stages, an interlayer dielectric (ILD) may be formed. Further in the depicted fabrication stages, the sacrificial gate structures may be removed and replacement gate structures 170 may be formed in place thereof.

In the depicted fabrication stages, one or more sacrificial gate structures (not shown) may be formed and may include a sacrificial gate liner (not shown), a sacrificial gate (not shown), and a sacrificial gate cap (not shown). The sacrificial gate structures may be formed by initially depositing a sacrificial gate liner layer (e.g., a dielectric, oxide, or the like) upon the one or more STI regions 130, upon and around the one or more nanolayer stacks 120, and within respective gate extension opening(s) 123 (shown in FIG. 4). The sacrificial gate structures may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks 120. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures may further be formed by patterning the gate cap layer, sacrificial gate layer, and sacrificial gate liner by, for example, using lithography and etch processes to remove undesired portions and retain desired portion(s), respectively. The retained portion(s) of the gate cap layer, sacrificial gate layer, and sacrificial gate liner may form the sacrificial gate liner (not shown), the sacrificial gate (not shown), and the sacrificial gate cap (not shown), respectively, of each of the one or more sacrificial gate structures.

One or more sacrificial gate structures can be formed on targeted regions or areas of semiconductor IC device 100 to define the length of one or more GAA FETs and to provide sacrificial material for yielding targeted GAA FET structure(s) in subsequent processing. According to an example, each sacrificial gate structure can have a height of between approximately 50 nm and approximately 200 nm, and a length of between approximately 10 nm and approximately 200 nm.

Further in the depicted fabrication stages, the bottom sacrificial nanolayer 104 may be selectively removed. The bottom sacrificial nanolayer 104 may be removed by a wet etch utilizing an etchant that targets the material of the bottom sacrificial nanolayer 104 selective to the respective material(s) of the sacrificial nanolayers 106, the active nanolayers 108, STI region(s) 130, and/or sacrificial gate structures, as appropriate. The etch may be timed or otherwise controlled to effectively remove the bottom sacrificial nanolayer 104 while substantially retaining the sacrificial nanolayers 106, the active nanolayers 108, the STI region(s) 130, and the sacrificial gate structures, etc. The removal of bottom sacrificial nanolayer 104 may form a bottom dielectric isolation (BDI) cavity between the substrate structure and the bottommost sacrificial nanolayer 106.

Further in the depicted fabrication stages, gate spacers 140 and BDI region 142 may be formed. One BDI region 142 may be formed within a respective BDI cavity within the one or more nanolayer stacks 120. The gate spacer(s) 140 may be formed upon the sidewall(s) of the sacrificial gate structures, upon the STI region(s) 130, and around the one or more nanolayer stacks 120.

The BDI region(s) 142 and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity (ies), upon STI regions 130, upon and around the one or more sacrificial gate structures, and upon and around the one or more nanolayer stack(s) 120. Subsequently, undesired portions of dielectric material may be removed while desired portions the dielectric material may be retained and thereby form the BDI region(s) 142 and the gate spacer(s) 140. The undesired portions of dielectric material may be removed by a directional ion etch, such as a reactive ion etch (RIE). The RIE may remove exposed or unprotected horizontal portions of the dielectric material while retaining protected horizontal portions of the dielectric layer (e.g., the BDI region(s) 142) and vertical portions of the dielectric layer (e.g., the gate spacer(s) 140).

Further in the depicted fabrication stages, source/drain (S/D) recesses 150 may be formed within the one or more nanolayer stacks 120 between gate spacers 140 of neighboring sacrificial gate structures. In other words, a single nanolayer stack 120 may be separated, by S/D recesses 150, into multiple nanolayer stacks 120 each located underneath a respective sacrificial gate structure. Further in the depicted fabrication stages, sacrificial nanolayers 106 may be indented and a respective inner spacer 144 may be formed in each indent.

The one or more S/D recesses 150 may be formed between adjacent sacrificial gate structures by removing respective portions of the sacrificial nanolayers 106 (shown in FIG. 4), active nanolayers 108, BDI region 142 that are between gate spacers 140 of adjacent or neighboring sacrificial gate structures. The one or more S/D recesses 150 may be formed to a depth to stop at the top surface of the substrate structure (e.g., the top surface of upper substrate 102, or the like), the top surface of STI regions 130, or the like. Alternatively, the one or more S/D recesses 150 may be formed to a depth within the upper substrate 102 above the etch stop layer 103 so that backside contact placeholder(s) 160 may be formed generally below a respective S/D region 164.

The undesired portions of sacrificial nanolayers 106, active nanolayers 108, and BDI region 142 may be removed by etching or other subtractive removal techniques. The top surface of the substrate structure may be used as an etch stop or other etch parameters may be controlled to stop the material removal at the substrate structure. As the gate spacers 140 and the sacrificial gate structures may be utilized to protect the underlying portions of sacrificial nanolayers 106, active nanolayers 108, and BDI region 142, respective sidewalls of the nanolayer stacks 120 may be substantially coplanar and substantially vertical with the outer sidewalls of the gate spacers 140 there above.

As used herein, “substantially vertical” sidewalls deviate from a direction normal to a major surface (e.g., top surface, etc.) of the substrate 102 by no more than 5°, e.g., 0°, 1°, 2°, 3°, 4°, or 5°, including ranges between any of the foregoing values.

Further, horizontal or lateral indents may be formed by laterally or horizontally removing respective portions of sacrificial nanolayers 106 within the nanolayer stacks 120. The indents may be formed by a reactive ion etch (RIE) process, which can remove portions of the sacrificial nanolayers 106. The horizontal depth of the indents may be chosen to set a length for a replacement gate structure 170 that is formed in place of one sacrificial gate structure. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers 106 generally below spacer 140) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 140, STI regions 130, and/or substrate structure.

Further in the depicted fabrication stages, a respective inner spacer 144 is formed within each indent. The one or more inner spacers 144 can be formed by ALD or CVD or any other suitable deposition technique that deposits a dielectric material within the indent(s), thereby forming the inner spacer(s) 144. In some examples, the inner spacer(s) 144 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, an isotropic etch process is performed to create substantially vertical sidewalls of the inner spacer(s) 144 that are coplanar with the substantially vertical sidewalls of the active nanolayers 108, of the gate spacers 140, and/or of the BDI region 142.

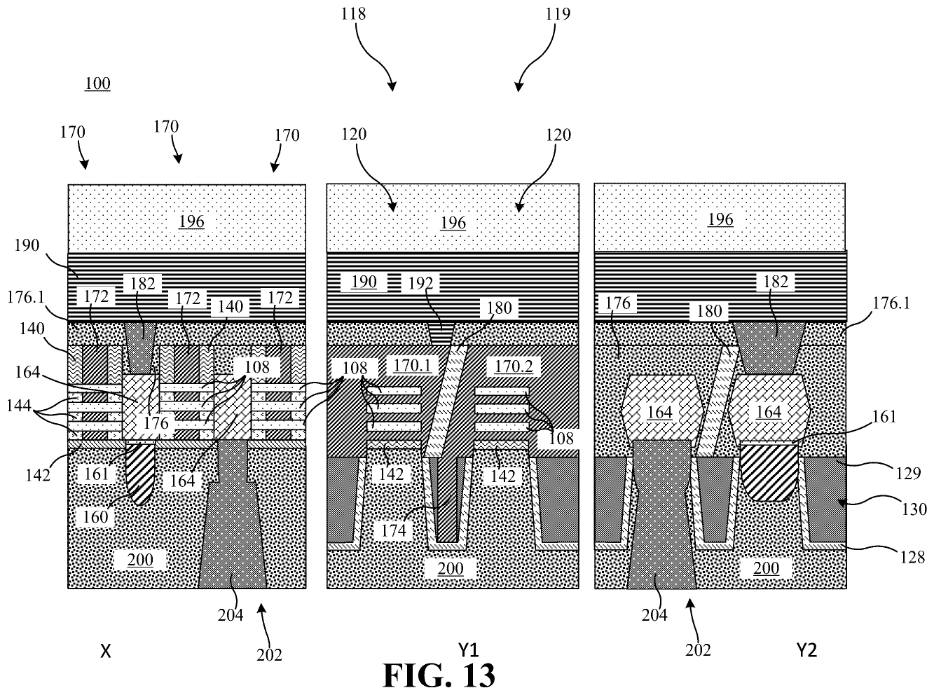

Further in the depicted fabrication stages, one or more backside contact placeholders 160 are formed within the substrate structure in between adjacent sacrificial gate structures within a respective S/D recess 150. In one example, the one or more backside contact placeholders 160 may be formed only in locations in which a backside contact, such as backside contact 204 depicted in FIG. 13, or the like, is to be formed. In an alternative example, a respective backside contact placeholder 160 may be formed in location(s) in which a backside contact is to be formed and in location(s) where a backside contact is not to be formed.

If the S/D recesses 150 are not already of sufficient depth to form the backside contact placeholders 160 within the substrate structure, the one or more backside contact placeholders 160 may be formed by initially forming one or more backside contact placeholder cavities within the substrate structure generally in between adjacent sacrificial gate structures and underneath respective one or more S/D recesses 150. For example, the one or more backside contact placeholder(s) cavities may be formed by a subtractive removal technique, such as an etch, that removes associated portion(s) of the upper substrate 102. The etch may be timed or otherwise controlled to stop the removal of the upper substrate 102 such that the depth or bottom of the one or more backside contact placeholder(s) cavities are above the etch stop layer 103.

The one or more backside contact placeholders 160 may be further formed by epitaxially growing an epitaxial material from exposed substrate structure surface(s) within the one or more backside contact placeholder(s) cavities. In some embodiments, epitaxial growth and/or deposition processes may be selective to forming on the semiconductor surfaces of the upper substrate 102, and may not deposit material on dielectric surfaces, such as silicon dioxide or silicon nitride surfaces. In some embodiments, the epitaxial growth of the one or more backside contact placeholders 160 may overgrow above the top surface of the substrate structure or above the top surface of BDI region(s) 142. In an example, the epitaxial material of the one or more backside contact placeholders 160 may be chosen to be etch selective to the material of the S/D region(s) 164, the material of the upper substrate 102, or the like. In another example, an etch stop layer 161 (e.g., a Si epitaxially grown layer, or the like) may be formed upon the top surface of the backside contact placeholders 160. For example, the one or more backside contact placeholders 160 may be SiGe and a Si etch stop layer 161 may be epitaxially grown from the top surface of the SiGe backside contact placeholders 160. Respective top surfaces of the backside contact placeholders 160 (or etch stop layer 161 thereupon) may be substantially horizontal and below the bottom surface of the bottommost active nanolayer 108 (e.g., to enable contact between such active nanolayer 108 and the S/D region 164) and/or substantially coplanar with a respective one or more top surface(s) of BDI region(s) 142.

Further in the depicted fabrication stages, a respective S/D region 164 is formed upon a backside contact placeholder 160. The S/D region 164 forms either a source or a drain, respectively, of respective transistor, such as a GAA FET, and is connected to respective a side or end surface of the active nanolayers 108 of a nanolayer stack 120. The S/D region 164 is composed of a semiconductor material and a dopant. As used herein, a “source/drain” region can be a source region or a drain region depending on subsequent wiring and application of voltages during operation of the transistor. The semiconductor material that provides each S/D region 164 is composed of one of the semiconductor materials mentioned above for the semiconductor structure. The semiconductor material that provides the S/D region 164 can be compositionally the same, or compositionally different from each active nanolayers 108. The dopant that is present in the S/D region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each S/D region 164 can have a dopant concentration of from 4×10²⁰ atoms/cm³ to 3×10²¹ atoms/cm³.

The one or more S/D regions 164 may be epitaxially grown or formed. In some examples, the S/D regions 164 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more S/D region 164 occurs or is promoted from the top surface of upper substrate 102, from the upper surface of backside contact placeholders 160 (or etch stop layer 161 thereupon), while epitaxial growth is limited or does not occur from neighboring STI regions 130.

In some embodiments, epitaxial growth to form the one or more S/D regions 164 may overgrow above the upper surface of the sacrificial gate structure(s) and be subsequently recessed such that the top surface of the S/D region 164 may be substantially horizontal and above the top surface of the topmost active nanolayer 108 within the nanolayer stacks 120 (e.g., to enable contact between such active nanolayer 108 and the S/D region 164).

Further in the depicted fabrication stages, an interlayer dielectric (ILD) 176 may be formed. For example, a blanket ILD 176 may be deposited over the S/D region(s) 164, over the STI region(s) 130, over the sacrificial gate structures, and over the gate spacers 140 associated with adjacent sacrificial gate structures.

The ILD 176 can be any suitable material, such as, for example, porous silicates, carbon doped oxides, silicon dioxides, silicon nitrides, silicon oxynitrides, OPL, or other dielectric materials. Any known manner of forming the ILD 176 can be utilized. The ILD 176 can be formed using, for example, CVD, PECVD, ALD, flowable CVD, spin-on dielectrics, or PVD.

In an example, the ILD 176 may be formed to a thickness above the top surface of the sacrificial gate structures. Subsequently, a planarization process, such as a CMP, may be performed to remove excess ILD 176 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures. The CMP may create a substantially planar or substantially horizontal top surface for the semiconductor IC device 100. In other words, the respective top surfaces of ILD 176, gate spacers 140, sacrificial gates, etc. may be substantially coplanar and/or substantially horizontal.

Further in the depicted fabrication stages, the sacrificial gate structures are removed and replacement gate structures 170 may be formed in place thereof. The sacrificial gate structures may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures. Appropriate etchants may be used that remove the sacrificial gate and/or sacrificial gate oxide selective to the active nanolayers 108, inner spacers 144, gate spacers 140, BDI region 142, STI regions 130, or the like. For clarity, the removal of the sacrificial gate structure further removes the sacrificial gate, sacrificial gate oxide, or the like that was within the gate extension opening 123.

Next, the active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 144, BDI region 142, gate spacers 140, or the like. After the removal of sacrificial nanolayers 106, void spaces may be formed above and/or below the active nanolayers 108.

Further, in the depicted fabrication stages, a replacement gate structure 170 is formed in place of the removed sacrificial gate structures around the active nanolayers 108, upon STI region(s) 130, upon BDI region(s) 142, and within the gate extension opening(s) 123.

Replacement gate structure(s) 170 may be formed by initially forming an interfacial layer (not shown) on the gate spacers 140, on the active nanolayers 108, on the BDI region 142, on the inner spacers 144, and within the gate extension opening(s) 123, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

Replacement gate structure(s) 170 may be further formed by forming a high-k layer (not shown) to cover the exposed surfaces of the interfacial layer. The high-K layer can be deposited by any suitable techniques, such as ALD, CVD, metal-organic CVD (MOCVD), PVD, thermal oxidation, combinations thereof, or other suitable techniques. A high-k material is a material with a higher dielectric constant than that of SiO₂, and can include e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-K layer can include, e.g., Ti, Ag, Al, TiAIN, TaC, TaCN, TaSiN, Mn, Zr, TiN, TaN, Ru, Mo, Al, WN, Cu, W, or any suitable materials.

Replacement gate structure(s) 170 may be further formed by depositing a work function (WF) gate (not shown) upon the high-layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-K layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structure(s) 170 may be further formed by depositing a conductive fill gate 172. In an example, when none of the previous replacement gate material(s) are utilized in the replacement gate structures 170, the conductive fill gate 172 may be formed upon the same or similar surfaces as those upon which the interfacial layer, described above, may be formed. In other examples, when one or more of the interfacial layer, the high-K layer, the WF gate, or the like, are utilized in the replacement gate structures, the conductive fill gate 172 may be formed upon the most recent formation thereof.

The conductive fill gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 176, gate spacers 140, replacement gate structure(s) 170, may be substantially horizontal and/or may be substantially coplanar.

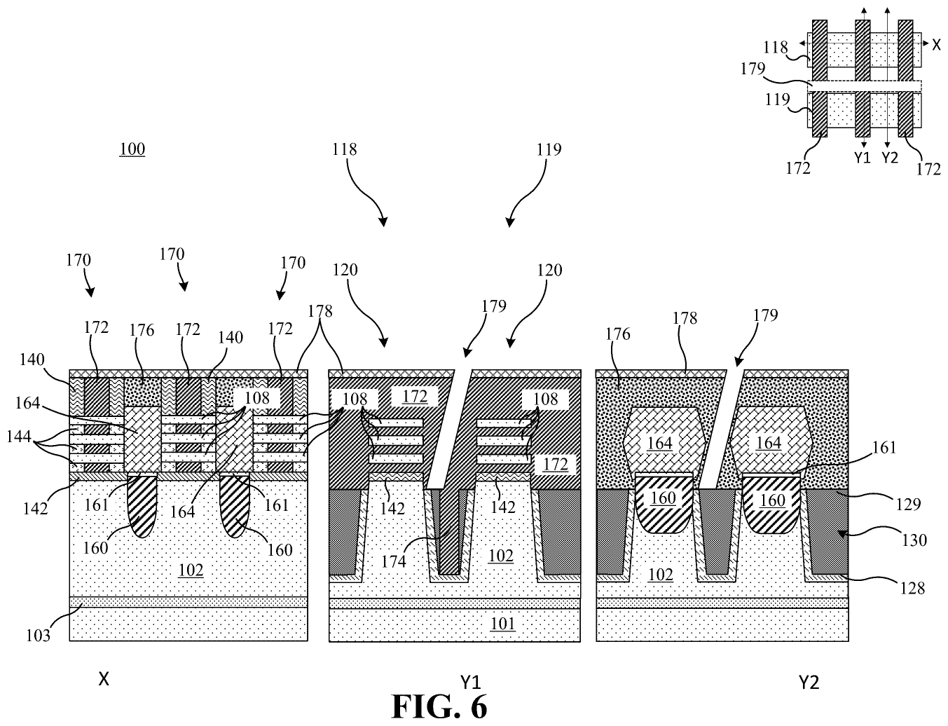

FIG. 6 depicts cross-sectional views of the semiconductor IC device 100 after fabrication operations, in accordance with embodiments of the present disclosure. In the depicted fabrication stages, a gate cut mask may be formed and patterned and an angled gate cut region opening may be formed.

For example, a gate cut mask 178 may be formed and patterned to create a gate cut opening is located between active region 118 and active region 119 and that spans multiple (e.g., two or more, or the like) replacement gate structures 170. The gate cut mask 178 which may consist of a nitride material, such as, but not necessarily limited to, silicon nitride (SiN) or titanium nitride (TiN), a low temperature oxide, such as an organic planarization layer (OPL), may be formed on the replacement gate structures 170, on the ILD 176, on the gate spacers 140. The gate cut mask 178 can be deposited using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), or the like.

Subsequently, a photoresist (not shown) may be formed over the gate cut mask 178. The photoresist may include a positive-tone photoresist composition, a negative-tone photoresist composition, or a hybrid-tone photoresist composition. A layer of photoresist material may be formed by a deposition process such as, for example, spin-on coating. The deposited photoresist may be subjected to a pattern of irradiation, and the exposed photoresist material is developed utilizing resist developer. The pattern provided by the patterned photoresist material is transferred through the gate cut mask 178 to form the gate cut opening therein. According to various embodiments, the areal dimensions of the gate cut opening are within lithography process windows for forming such structure(s).

The pattern transfer etching process to form the gate cut opening may be an anisotropic etch. In certain embodiments, a dry etching process such as, for example, reactive ion etching (RIE) can be used. In other embodiments, a wet chemical etchant can be used. In still further embodiments, a combination of dry etching and wet etching can be used.

Further in the depicted fabrication stage, angled gate cut region opening 179 may be formed. The angled gate cut region opening 179 may be formed using the gate cut mask 178 and subjecting the semiconductor IC device 100 to a etch stage that utilizes a highly directional beam of ions that are angled relative to the semiconductor IC device 100, to remove portions of the replacement gate structure 170 and portions of the ILD 176 under the gate cut opening. The angled etch of the replacement gate structure 170 and the ILD 176 may generally stop at one or more applicable STI regions 130 thereunder.

The highly directional beam of ions may angled relative to the semiconductor IC device 100 by first directing the highly directional beam of ions toward the semiconductor IC device 100 in the direction normal to the major surface (e.g., top surface, etc.) of the substrate structure and diverting, angling, or the like, at least a portion of the highly directional beam of ions (hereinafter referred to highly directional angled beam of ions) prior to the highly directional angled beam of ions colliding with the semiconductor IC device 100. The highly directional beam of ions may be angled or diverted by a faraday cage, tilting or angling the semiconductor IC device 100 with respect to the highly directional beam of ions, or the like.

The highly directional angled beam of ions may form the angled gate cut region opening 179 within the replacement gate structures 170 and within the ILD 176 between adjacent S/D region 164. The mouth or top area of the angled gate cut region opening 179 may be located between active region 118 and active region 119 but nearest active region 119, as is depicted in the partial top-down view in FIG. 6. In proportion to a depth of the angled gate cut region opening 179, the angled gate cut region opening 179 may be angled toward the active region 118, as is depicted in the partial top-down view in FIG. 6. In this manner, a well or bottom area of the angled gate cut region opening 179 may be located nearest the active region 118.

For clarity, the highly directional angled beam of ions that can collide with semiconductor IC device 100 may be similarly angled, prior to colliding with semiconductor IC device 100. Consequently, one or more sidewalls of the angled gate cut region opening 179 may be substantially parallel, as depicted. As used herein, “substantially parallel” sidewalls deviate relative thereto by no more than 5°, e.g., 0°, 1°, 2°, 3°, 4°, or 5°, including ranges between any of the foregoing values. Similarly, as used herein, “substantially angled” sidewalls deviate from the direction normal to the major surface (e.g., top surface, etc.) of the substrate 102 by more than 5°, e.g., 6°, 7°, 8°, 9°, 10°, or greater, including ranges between any of the foregoing values.

For clarity, as depicted, the angle of the highly directional angled beam of ions may be chosen so that the well or bottom surface of the resulting angled gate cut region opening 179 lands on the STI region 130 that is located between active regions 118 and 119. Further, the angle of the highly directional angled beam of ions may further be chosen so that the resulting substantially angled sidewalls of the angled gate cut region opening 179 are substantially parallel to one or more diamond (111) epitaxial surfaces of the S/D regions 164 that are separated by the angled gate cut region opening 179. For example, as depicted in the Y2 view, the substantially angled sidewalls of the angled gate cut region opening 179 may be substantially parallel to a first diamond (111) epitaxial surface of the S/D region 164 in active region 118 and to a second diamond (111) epitaxial surface of the S/D region 164 in active region 119.

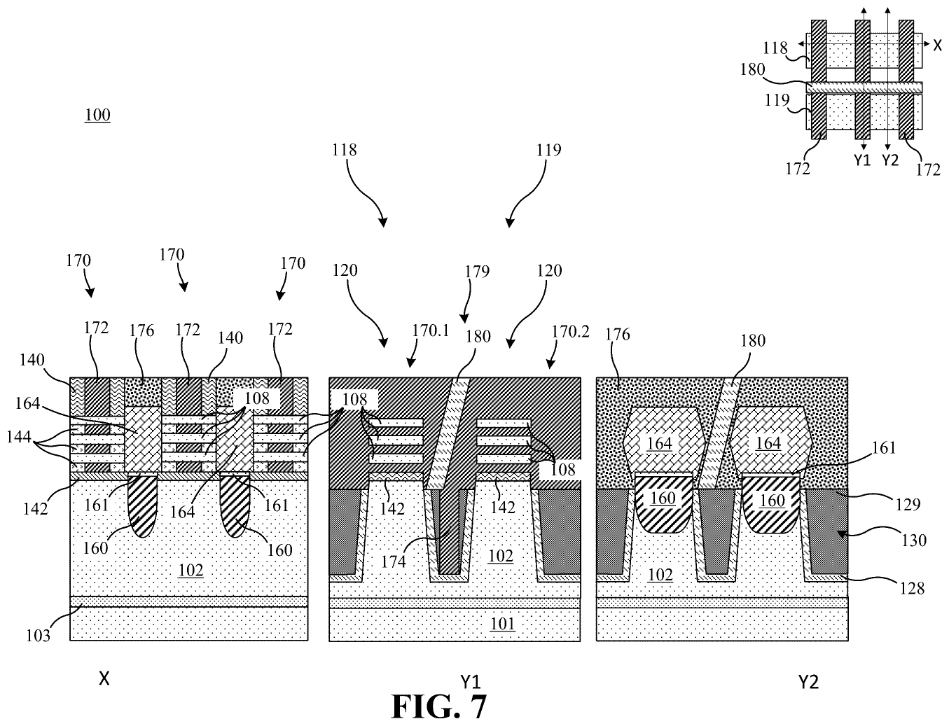

FIG. 7 depicts cross-sectional views of semiconductor IC device 100 shown after representative fabrication operation(s), in accordance with one or more embodiments. In the depicted fabrication stage, an angled gate cut region 180 may be formed within angled gate cut region opening 179.

The angled gate cut region 180 may be formed by depositing a gate cut dielectric material, such as, for example, porous silicates, carbon doped oxides, silicon dioxides, silicon nitrides, silicon oxynitrides, or other dielectric materials. Any appropriate deposition technique for forming the gate cut dielectric layer can be utilized. The gate cut dielectric layer can be formed using, for example, CVD, PECVD, ALD, flowable CVD, spin-on dielectrics, or PVD.

In an embodiment, the gate cut dielectric layer may be formed within the angled gate cut region opening 179 and upon the STI region 130 therewithin, upon the ILD 176, upon the gate spacers 140, upon the replacement gate structure(s) 170, or the like, to a thickness above the replacement gate structures 170 and subsequently planarized by a subtractive removal technique, such as a CMP. Generally, the gate cut dielectric layer material that remains within the angled gate cut region opening 179 may form the angled gate cut region 180. After the planarization process, the respective top surfaces of the replacement gate structures 170, gate spacers 140, ILD 176, and angled gate cut region 180 may be substantially coplanar and/or substantially horizontal.

For clarity, the angled gate cut region 180 generally divides or separates one or more replacement gate structures 170 into a first gate or gate structure and a second gate or gate structure, which may be referred herein as a first gate structure 170.1 and a second gate structure 170.2. The angled gate cut region 180 may further adequately electrically isolate the first gate structure 170.1 and the second gate structure 170.2 from one another. The first gate structure 170.1 may be associated with a first series of active nanolayer 108 channels within active region 118. The second gate structure 170.2 may be associated with a second series of active nanolayer 108 channels within active region 119. Further, the angled gate cut region 180 may generally separate S/D region(s) 164 that are in active region 118 from S/D region(s) 164 that are in active region 119.

The second gate structure 170.2 illustratively includes the backside gate extension 174 that extends from the backside thereof. In some embodiments of the disclosure, the angled gate cut region 180 may be located or positioned to effectively separate the backside gate extension 174 from the active region 118 to achieve an electrical node that consists of the backside gate extension 174 and the second gate structure 170.2 that is adequately electrically isolated from the first gate structure 170.1.

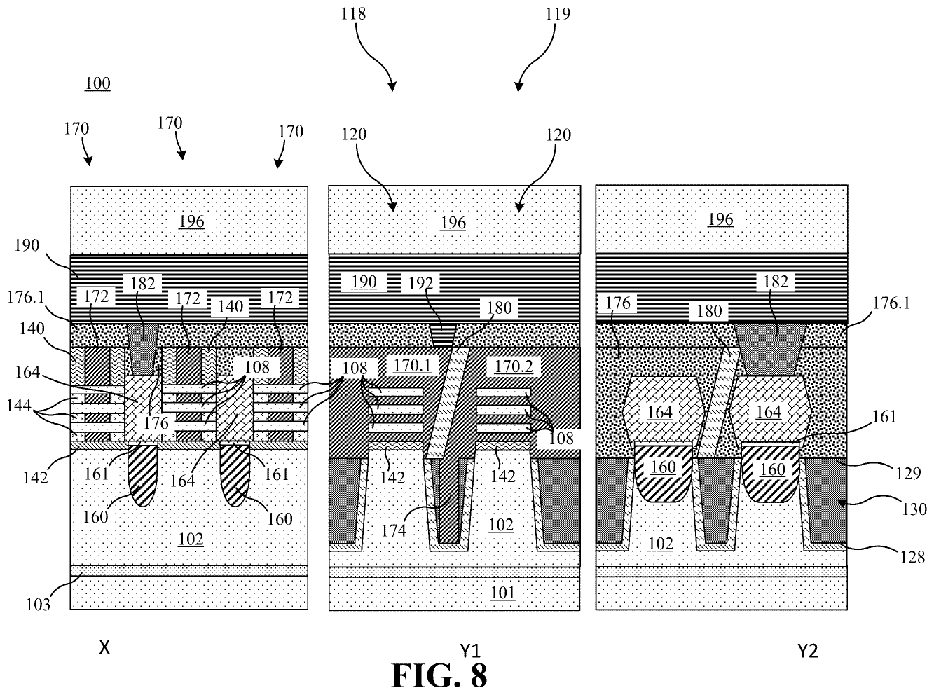

FIG. 8 depicts cross-sectional views of the semiconductor IC device 100 after fabrication operations, in accordance with embodiments of the present disclosure. In the depicted fabrication stages, ILD 176.1 may be formed, one or more frontside contact(s) 182 may be formed, a frontside BEOL network 190 may be formed, and a carrier wafer 196 is attached.

The ILD 176.1 may be formed upon respective top surfaces of replacement gate structure(s) 170, ILD 176, gate spacers 140, and angled gate cut region 180. The ILD 176.1 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 176.1 can be utilized. The ILD 176.1 can be formed using, for example, CVD, PECVD, ALD, flowable CVD, spin-on dielectrics, or PVD.

The frontside contact(s) 182 may be formed by patterning respective frontside contact openings within ILD 176.1, ILD 176, or the like, from the frontside (i.e., from above the semiconductor IC device 100, as depicted, downward to respective structures thereof). The frontside contact(s) 182 may be in direct or indirect physical and electrical contact and/or may physically meld with respective material(s) of one or more regions of the semiconductor IC device 100. For example, the illustrated frontside contact 182 is in direct contact with S/D region 164 within active region 119. Similarly, other frontside contact(s) 182 (not shown) may be in direct contact with other S/D regions 164, with one or more replacement gate structures 170, or the like.

The frontside contact(s) 182 may be formed by initially forming frontside contact opening(s). The frontside contact opening(s) may be formed by the same or shared lithography and etch process(es), or sequential lithography and etch processes. In such process(es), a mask may be applied and patterned. An opening in the patterned mask may expose the portion of the underlying ILD 176.1 and/or ILD 176 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 182 may be further formed by depositing conductive material such as metal into the respective frontside contact opening(s). In an example, frontside contact(s) 182 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, conductive fill. Subsequently, the respective top surfaces of frontside contact(s) 182 and ILD 176.1 may be coplanar. In embodiments, the frontside contact(s) 182 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

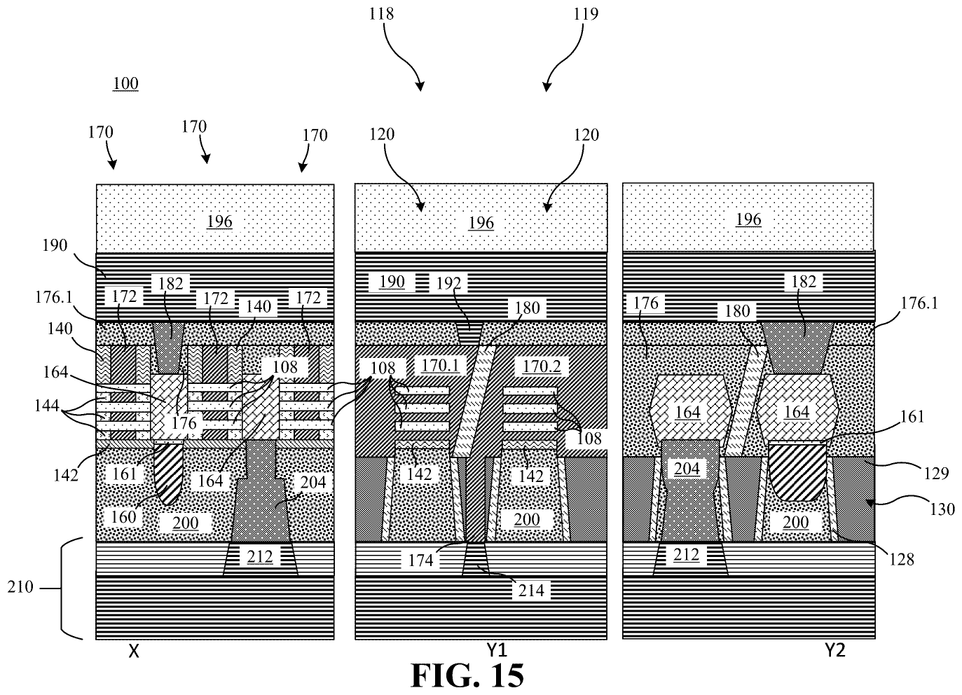

BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 190 is formed on the frontside of the semiconductor device 100. Subsequently, a backside BEOL network 210, as depicted in FIG. 15 is formed.

In the depicted example, the frontside BEOL network 190 is formed over the ILD 176.1 and upon the frontside contact(s) 182. Respective wires within the frontside BEOL network 190 may be electrically connected to the one or more S/D regions 164, one or more replacement gate structure(s) 170, or the like, by a respective frontside contact(s) 182. For example, respective wires within the frontside BEOL network 190 may be electrically connected to the S/D region 164 by frontside contact 182. Alternatively, respective wires within the frontside BEOL network 190 may be electrically connected to the one or more S/D regions 164, one or more replacement gate structure(s) 170, or the like, by a lowest interconnect, such as a vertical interconnect access (VIA), such as VIA 192, that is within the frontside BEOL network 190.

The frontside BEOL network 190 is located directly on the frontside surface of the MOL structure (e.g., ILD 176.1, frontside contact(s) 182, etc.). The frontside BEOL network 190 can include one or more interconnect dielectric material layers (including one of the dielectric materials mentioned above for the frontside ILD 176) and contains frontside metal wires (the metal wires can be composed of any electrically conductive metal or electrically conductive metal alloy) embedded therein. In some embodiments, the frontside metal wires within the frontside BEOL network 190 are composed of Cu. The frontside BEOL network 190 can include “x” numbers of frontside metal levels, wherein “x” is an integer starting from 1. The frontside BEOL network 190 may further contain conductive pads that are connected to one or more of the metal wires and may be used to connect the semiconductor IC device to an external and/or higher-level structure, such as a chip carrier, motherboard, or the like.

For clarity, a first conductive pathway formed of first respective wires within the frontside BEOL network 190 may be electrically connected to S/D region 164 by frontside contact 182. Similarly, a second conductive pathway formed of second respective wires within the frontside BEOL network 190 may be electrically connected to the first gate structure 170.1 by VIA 192.

The carrier wafer 196 can include one of the semiconductor materials mentioned above for the semiconductor structure. Carrier wafer 196 may be attached to the semiconductor IC device 100 by a wafer-to-wafer bonding technique.

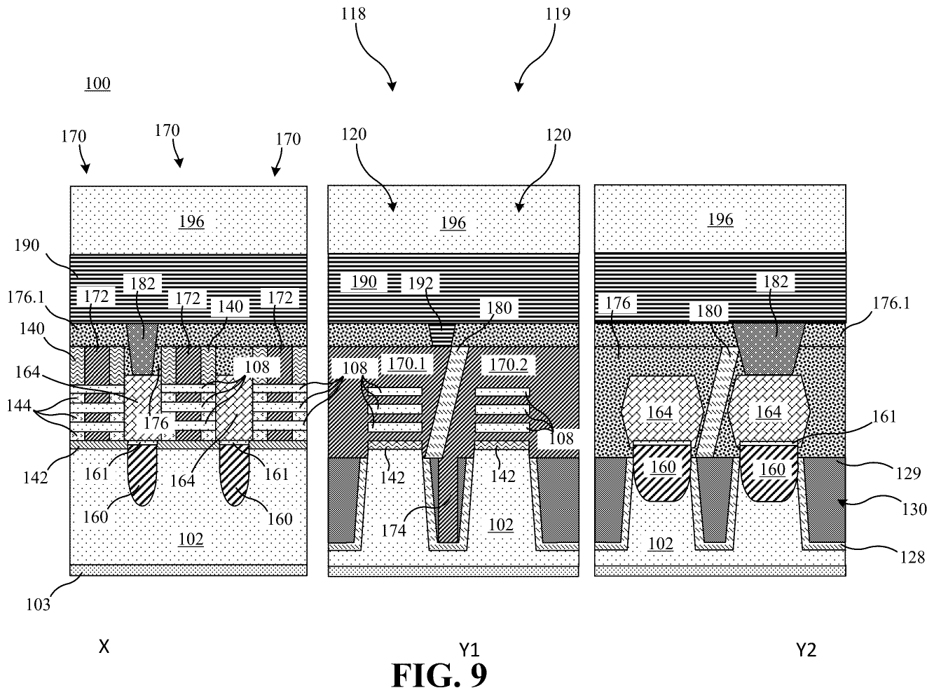

FIG. 9 depicts cross-sectional views of the semiconductor IC device 100 after fabrication operations, in accordance with embodiments of the present disclosure. In the depicted fabrication stages, the substrate structure may be recessed. For example, the lower substrate 101 may be removed.

The substrate structure may be recessed by flipping the semiconductor IC device 100 (not shown) and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

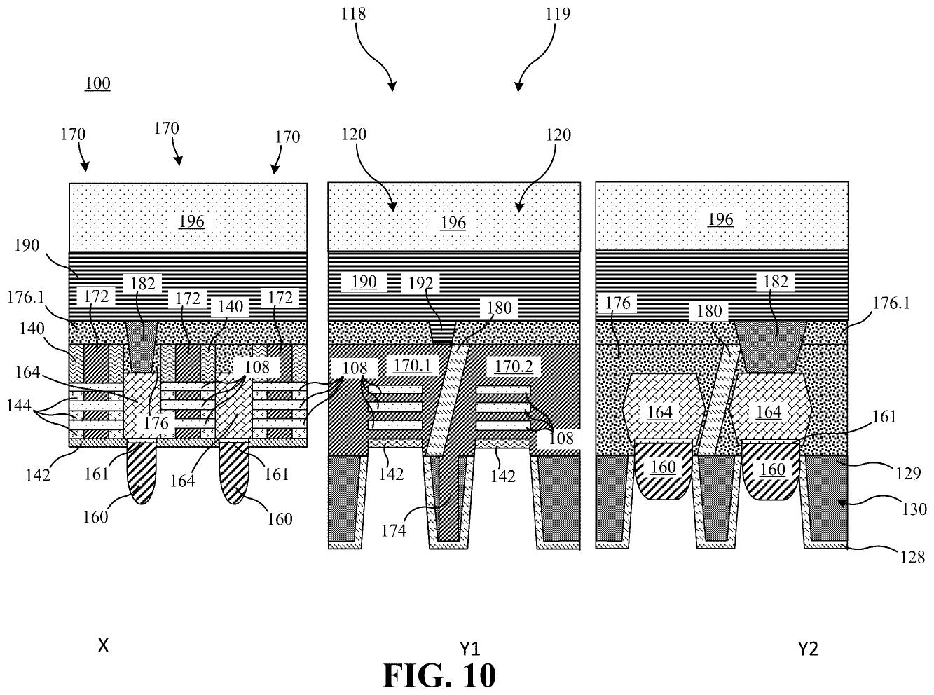

FIG. 10 depicts cross-sectional views of the semiconductor IC device 100 after fabrication operations, in accordance with embodiments of the present disclosure. In the depicted fabrication stages, the remaining substrate structure may be removed. For example, etch stop layer 103 and the upper substrate 102 may be removed.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

Subsequently, the upper substrate 102 is removed by an appropriate substrative removal technique, such as an etch, that removes associated portion(s) of the upper substrate 102. The etch may be timed or otherwise controlled to remove the material of substrate 102 and retain or otherwise expose the STI regions 130, retain and partially expose one or more backside contact placeholders 160, and retain and expose the BDI region(s) 142.

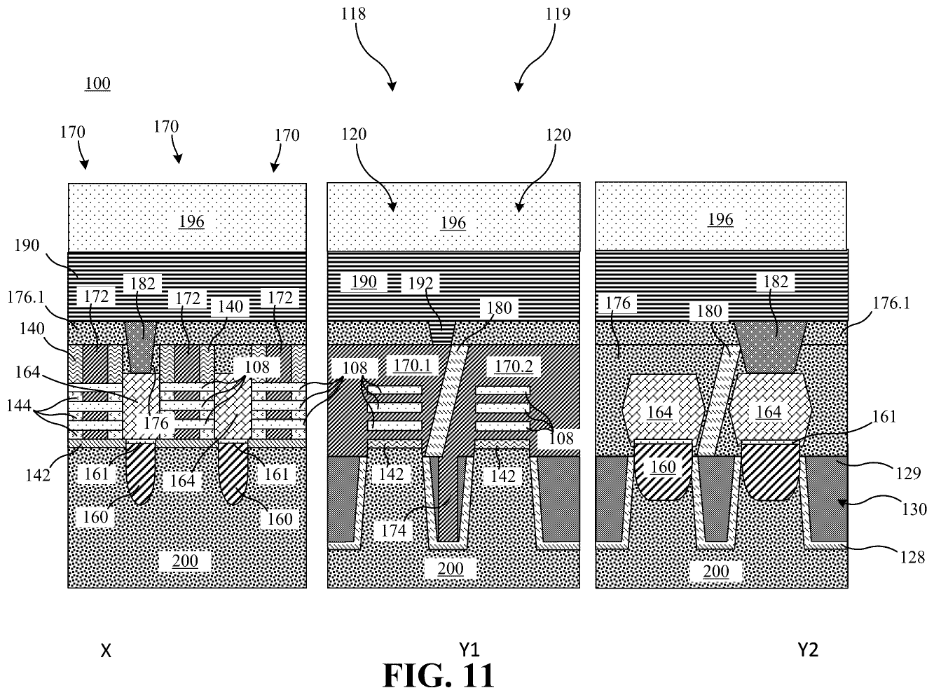

FIG. 11 depicts cross-sectional views of semiconductor IC device 100 shown after exemplary fabrication operation(s), in accordance with one or more embodiments. In the depicted fabrication stage, backside ILD 200 may be formed upon the exposed backside of the semiconductor IC device 100.

The backside ILD 200 may be formed upon the respective exposed backside surfaces (e.g., those surfaces that were exposed by the removal of the substrate structure, etc.) of the STI regions 130, the backside contact placeholder(s) 160, and the BDI region(s) 142. The backside ILD 200 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 200 can be utilized. The backside ILD 200 can be formed using, for example, CVD, PECVD, ALD, flowable CVD, spin-on dielectrics, or PVD. In an example, the backside ILD 200 may be formed to a thickness below (as depicted) the bottom surface of the STI regions.

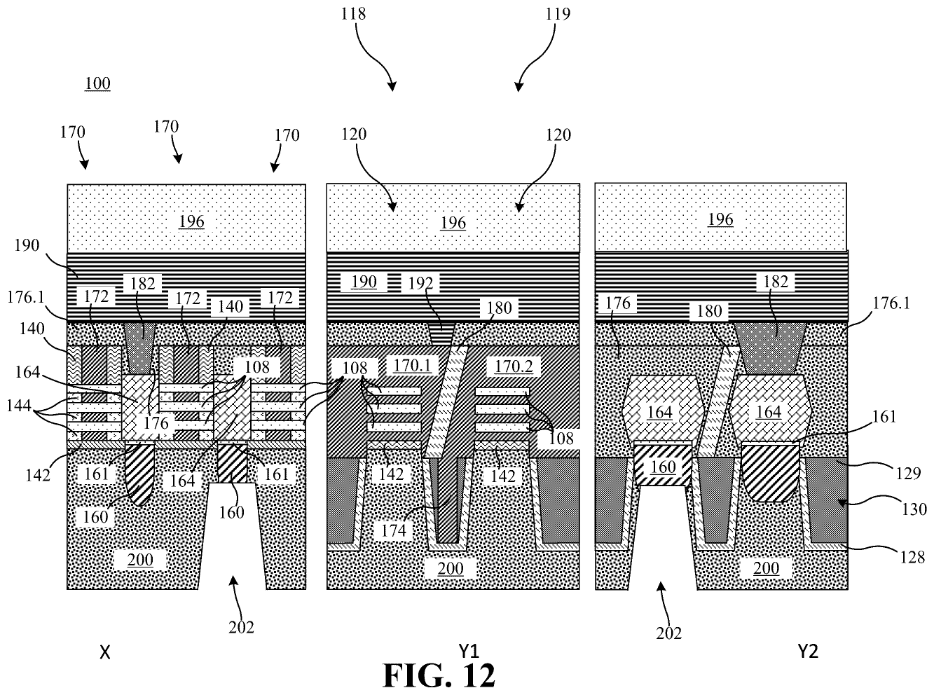

FIG. 12 depicts cross-sectional views of semiconductor IC device 100 shown after exemplary fabrication operation(s), in accordance with one or more embodiments. In the depicted fabrication stage, backside contact opening(s) 202 may be formed within backside ILD 200. For clarity, a particular backside contact opening 202 is depicted and is associated with the backside contact placeholder 160 that is below the S/D region 164 in the active region 118.

The backside contact opening(s) 202 may be formed by the same or shared lithography and etch process(es), or sequential lithography and etch processes. In such process(es), a mask may be applied to the backside of the backside ILD 200 and patterned. Openings in the patterned mask may expose the portion of the underlying backside ILD 200 to be removed while other protected portions of semiconductor IC device 100 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

In the depicted example, the backside contact opening 202 is formed within backside ILD 200. This backside contact opening 202 exposes the and/or partially removes a portion of the backside contact placeholder 160 there above (as depicted).

FIG. 13 depicts cross-sectional views of semiconductor IC device 100 shown after exemplary fabrication operation(s), in accordance with one or more embodiments. In the depicted fabrication stage, the backside contact placeholder(s) 160 that are exposed by a respective backside contact opening 202 may be removed and backside contact(s) 204 may be formed within the backside contact opening(s) 202.

The backside contact placeholder(s) 160 that are exposed by respective backside contact openings 202 may be removed by a substrative removal technique, such as an etch. In one example, the entire applicable contact placeholder(s) 160 may be removed. In another example, the lower portion of the backside contact placeholder is removed using the etch stop layer 161 top surface of the backside contact placeholder 160 as an etch stop to protect the S/D region 164 there above. Optionally, at the present fabrication stage and as depicted, respective etch stop layer(s) 161 may also be removed thereby exposing at least a portion of the S/D region(s) 164 there above.

Further in the depicted fabrication stage, a respective backside contact 204 may be formed within a backside contact opening(s) 202. The backside contact(s) 204 may be formed by depositing conductive material, such as metal, into the respective backside contact opening(s) 202. In an example, backside contact(s) 204 may be formed by depositing a liner, such as Ni, NiPt or Ti, etc. into the backside contact opening(s) 202, depositing an adhesion liner, such as TiN, TaN, etc. upon the liner, and by depositing a conductive fill, such as Al, Ru, W, Co, Cu, etc. upon the adhesion liner.

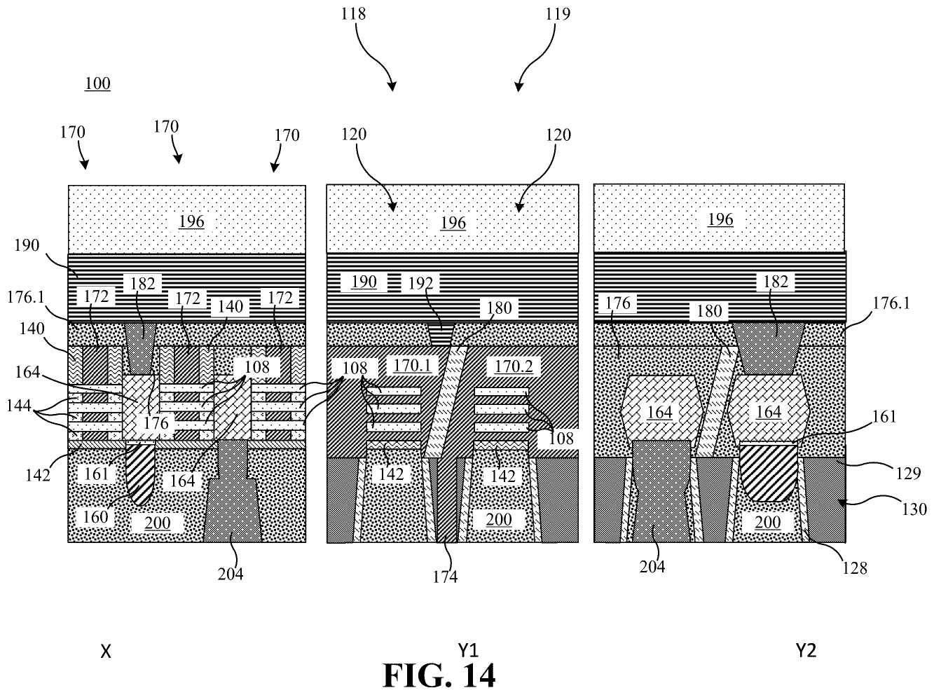

FIG. 14 depicts cross-sectional views of semiconductor IC device 100 shown after exemplary fabrication operation(s), in accordance with one or more embodiments. In the depicted fabrication stage, a planarization process, such as a CMP process or a mechanical grinding process, may remove excess portions of the backside contact(s) 204, may remove excess portions of STI region(s) 130, may remove excess portions of backside ILD 200, or the like, and may expose at least a portion of the backside gate extension 174.

As is illustrated, a planarization process may expose a bottom surface (as depicted) of the backside gate extension 174. Subsequently, the respective bottom surfaces (as depicted) of backside contact(s) 204, backside gate extension 174, STI region(s) 130, and backside ILD 200 may be substantially horizontal and/or substantially coplanar.

FIG. 15 depicts cross-sectional views of semiconductor IC device 100 shown after exemplary fabrication operation(s), in accordance with one or more embodiments. In the depicted fabrication stage, a backside BEOL network 210 may be formed.

The backside BEOL network 210 may be formed over the backside ILD 200, over one or more backside contact(s) 204, over the backside gate extension 174, or the like. The backside BEOL network 210 may be indirectly electrically and/or indirectly physically connected to the one or more S/D regions 164 by way of a particular backside contact 204. For example, as illustrated, a backside VIA 214 within the backside BEOL network 210 may be connected to the backside gate extension 174. The backside VIA 214 may be further connected to a first electrical pathway of a first series of wires and/or interconnects within the backside BEOL network 210. Similarly, a backside VIA 212 within the backside BEOL network 210 may be connected to a S/D region 164 by way of a particular backside contact 204. The backside VIA 212 may be connected to a second electrical pathway of a second series of wires and/or interconnects within the backside BEOL network 210.

The backside BEOL network 210 can include one or more interconnect dielectric material layers (including one of the dielectric materials mentioned above for the ILD 176) and contains backside conductive wires and/or interconnects, such as VIAs, embedded therein. In some embodiments, the backside wires within the backside BEOL network 210 are composed of Cu. The backside BEOL network 210 can include “x” numbers of backside metal levels, wherein “x” is an integer starting from 1. If not included in frontside BEOL network 190, backside BEOL network 210 may further contain conductive pads that are connected to one or more of the backside metal wires and may be used to connect the semiconductor IC device 100 to the external and/or higher-level structure.

In an example, signal routing and power routing is effectively split between the frontside BEOL network 190 and the backside BEOL network 210. For example, at least 90% of the frontside metal wires (e.g., furthest from the transistor(s)) are signal routing metal wires and the remainder frontside metal wires which are usually present in metal levels closest to the transistor, can be used as power routing wires. Further in this example, at least 90% of the backside metal wires that are in metal levels closest to the transistor(s) are power routing metal wires and the remainder backside metal wires which are usually present in metal levels furthest away from the transistor, can be used as signal routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 210 may be a backside power distribution network (BSPDN).

The backside BEOL network 210 includes various wiring levels. The wiring levels may alternate between a VIA level and a metal level. To form a VIA level, an associated dielectric passivation layer may be formed, the dielectric passivation layer may be patterned to create a VIA opening therein, and conductive or metal material may be deposited within the VIA opening to form a via contact. A VIA, such as VIA 212, 214 within a lowest via level within the backside BEOL network 210 may connect either directly or indirectly to an associated structure.

To form a metal level, an associated dielectric passivation layer may be formed, the dielectric passivation layer may be patterned to create a wiring trench therein, and conductive or metal material may be deposited within the wiring trench to form a wire. A wire, such as within a lowest metal level may connect directly one or more VIAs or backside contact(s) 204.

For clarity, semiconductor IC device 100 includes at least the angled gate cut region 180 and may further include a first transistor and a second transistor. The first transistor may include a first gate, such as a replacement gate structure 170.1, that is around and that contacts each of a first series of vertically stacked channels, such as active nanolayers 108. The first transistor may further include source/drain regions, such as S/D regions 164, that are connected to respective end surfaces of the first series of vertically stacked channels. Similarly, the second transistor may include a second gate, such as a replacement gate structure 170.2, that is around and that contacts each of a second series of vertically stacked channels, such as active nanolayers 108. The second transistor may further include source/drain regions, such as S/D regions 164, that are connected to respective end surfaces of the second series of vertically stacked channels.

According to one or more embodiments, the angled gate cut region 180 may separate the first gate from the second gate. For example, the angled gate cut region 180 may be located between and adequately electrically isolate the replacement gate structure 170.1 from the replacement gate structure 170.2. Similarly, the angled gate cut region 180 may separate at least one of the S/D regions of the first transistor from at least one of the S/D regions of the second transistor.

The first series of vertically stacked channels may be included in active region 118. In some implementations, a channel width of the first series of vertically stacked channels may define the width of the first active region 118. Similarly, the second series of vertically stacked channels may be included in a second active region 119, in which the channel width of the second series of vertically stacked channels may define the width of the second active region 119. In some embodiments of the disclosure, and as depicted, the angled gate cut region 180 may be located between the first active region 118 and the second active region 119.

The first gate may include a frontside in which a frontside gate contact is joined thereto. The frontside gate contact may be a middle-of-line (MOL) type contact that connects the first gate with a frontside back-end-of-line (BEOL) network 190 or alternatively, and as depicted, may be an interconnect, such as VIA 192, within a lowest level of the frontside BEOL network 190. In some embodiments of the disclosure, and as depicted, this frontside contact may be located between the first active region 118 and the second active region 119.

The second gate may include a backside from which the backside gate extension 174 protrudes. In some embodiments of the disclosure, and as depicted, the backside gate extension 174 may be located between the first active region 118 and the second active region 119. A backside gate contact may be joined to the backside gate extension 174. The backside gate contact may be a MOL type contact that connects the backside gate extension 174 to a backside BEOL network 210 or alternatively may be an interconnect, such as VIA 214, within a lowest level of the backside BEOL network 210.

The frontside BEOL network 190 may be connected to one or more of the S/D regions by a respective frontside contact, such as frontside contact(s) 182. As depicted, the frontside contact may be a MOL type contact that connects a respective S/D region with the frontside BEOL network 190. The backside BEOL network 210 may be connected to one or more of the S/D regions by a backside contact, such as backside contact 204.

The semiconductor IC device 100 may be fabricated by semiconductor IC device fabrication techniques that allow for the frontside, such as VIA 192, to connect against a frontside of the first gate and that allow for the backside contact, such as VIA 214, to connect against a backside of a second gate (e.g., by way of backside gate extension 174, or the like). To achieve these and potential other benefits, the semiconductor IC device 100 includes the angled gate cut region 180 that may allow for adequate first gate frontside area to which the frontside contact may be joined and that may allow for adequate second gate backside area to which the backside contact may be joined.

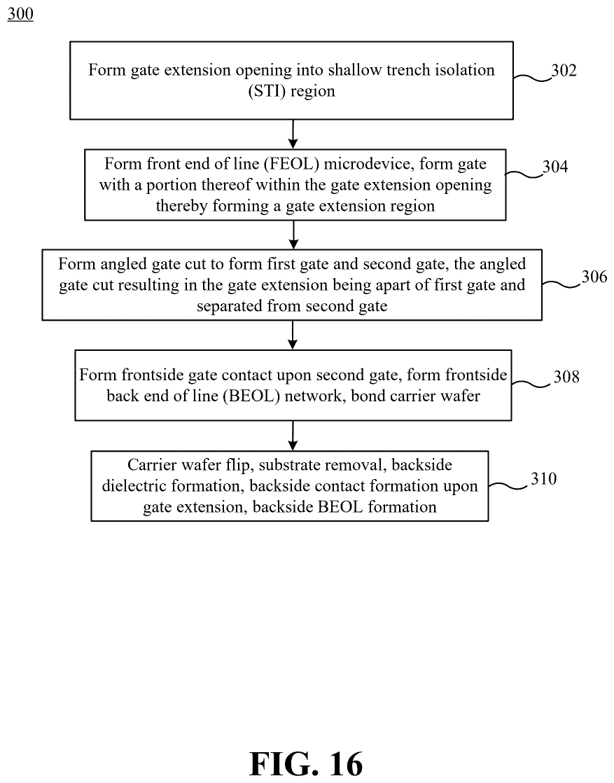

FIG. 16 depicts a flow diagram illustrating method 300 to fabricate a semiconductor IC device, such as semiconductor IC device 100. The depicted fabrication operations of method 300 are illustratively depicted and described above with reference to one or more of FIG. 3 through FIG. 15 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a gate extension opening within a shallow trench isolation (STI) region. For example, method 300 may include forming a backside gate extension opening 123 within a STI region 130 that is between a first active region 118 and a second active region 119.

At block 304, method 300 may further continue with forming a front end of line (FEOL) microdevice, such as a transistor, and/or with, more particularly, forming a gate or other electrode associated with the FEOL microdevice, such that a portion of the gate is formed within the backside gate extension opening to thereby form an associated backside gate extension. For example, one or more transistors, such as GAA FETs, are formed and a replacement gate structure 170 is formed upon and/or around channels of the one or more transistors. A portion of the replacement gate structure 170 may be formed within the gate extension opening 123 which may effectively form the backside gate extension 174.

At block 306, method 300 may continue with forming an angled gate cut region that separates the gate into a first gate and a second gate, the angled gate cut region results in the backside gate extension connected to or protruding from the backside of the first gate and also separating the backside gate extension from the second gate. For example, angled gate cut region 180 is formed between active region 118 and active region 119 and may split or separate the replacement gate structure into a first gate (e.g., replacement gate structure 170.1) and a second gate (e.g., replacement gate structure 170.2). The angled gate cut region 180 may land on the STI region 130 that is between the active region 118 and active region 119. The angle of the gate cut region 180 may be chosen to be substantially parallel with one or more diamond (111) epitaxial surfaces of one or more of the S/D regions of the first and second transistors within active region 118 and active region 119, respectively.

At block 308, method 300 may continue with forming a frontside contact that is connected to or joined with the second gate, with forming a frontside BEOL network, and with bonding a carrier wafer thereto. For example, a VIA 192 style contact within the lowest level within the frontside BEOL network 190 may be formed directly upon the frontside or top surface of the first gate (e.g., replacement gate structure 170.1). Subsequently, the remaining frontside BEOL network 190 may be formed and a carrier wafer 196 may be bonded thereto.

At block 310, the semiconductor IC device may be flipped, a substrate associated with the FEOL microdevice may be removed, a backside ILD may be formed, and a backside contact may be formed over the backside gate extension, and a backside BEOL network may be formed. For example, once the substrate structure is removed the backside ILD 200 may formed upon the backside of the semiconductor IC device 100. Subsequently, ILD 200 may be patterned to form backside contact openings 202 and a backside contact 204 may be formed within a particular backside opening. Subsequently, a CMP process may remove excess backside contact 204 material and may further expose the backside gate extension 174. Subsequently, the backside BEOL network 210 may be formed upon the backside of semiconductor IC device 100. A backside contact, such as VIA 214 within the lowest level within the backside BEOL network 210 may be formed over the backside gate extension 174. Subsequently, the remaining backside BEOL network 210 may be formed.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first transistor comprising a first gate and a second transistor comprising a second gate that includes a backside gate extension;
an angled gate cut region that separates the first gate from the second gate;
a frontside gate contact connected to the first gate; and
a backside gate contact that is connected to the backside gate extension.

2. The semiconductor IC device of claim 1,
wherein the first transistor further comprises a first pair of source/drain (S/D) regions and the second transistor further comprises a second pair of S/D regions; and
wherein the angled gate cut region separates the first pair of S/D regions from the second pair of S/D regions.

3. The semiconductor IC device of claim 2, further comprising:
a frontside back end of line (BEOL) network connected to the frontside gate contact; and
a backside BEOL network connected to the backside gate contact.

4. The semiconductor IC device of claim 3, wherein one of the first pair of S/D regions is connected to the frontside BEOL network by a frontside S/D contact and the other of the first pair of S/D regions is connected to the backside BEOL network by a backside S/D contact.

5. The semiconductor IC device of claim 1, further comprising:
a shallow trench isolation (STI) region underneath and between the first transistor and the second transistor.

6. The semiconductor IC device of claim 5, wherein the backside gate extension extends through the STI region.

7. The semiconductor IC device of claim 5, wherein a bottom surface of the angled gate cut region is substantially coplanar with a top surface of the STI region.

8. The semiconductor IC device of claim 1, wherein the frontside gate contact, the backside gate contact, and the backside gate extension are located between a boundary of the first transistor and a boundary of the second transistor.

9. The semiconductor IC device of claim 3, wherein the frontside gate contact is a vertical interconnect access (VIA) contact within the frontside BEOL network and wherein the backside gate contact is a VIA contact within the backside BEOL network.

10. A semiconductor integrated circuit (IC) device comprising:
a first transistor associated with a first active region and comprising a first gate;
a second transistor associated with a second active region and comprising a second gate; and
an angled gate cut region between the first active region and the second active region that separates the first gate from the second gate.

11. The semiconductor IC device of claim 10, wherein a top surface area of the angled gate cut region is located closer to the first active region relative to the second active region and wherein a bottom surface area of the angled gate cut region is located closer to the second active region relative to the first active region.

12. The semiconductor IC device of claim 10, further comprising:
a backside gate contact that is connected to a backside of the first gate; and
a frontside gate contact connected to a frontside of the second gate.

13. The semiconductor IC device of claim 12:
wherein the first transistor further comprises a first pair of source/drain (S/D) regions;
wherein the second transistor further comprises a second pair of S/D regions; and
wherein the angled gate cut region further separates the first pair of S/D regions from the second pair of S/D regions.

14. The semiconductor IC device of claim 13, further comprising:
a frontside back end of line (BEOL) network connected to the frontside gate contact; and
a backside BEOL network connected to the backside gate contact.

15. The semiconductor IC device of claim 14, wherein one of the first pair of S/D regions is connected to the frontside BEOL network by a frontside S/D contact and the other of the first pair of S/D regions is connected to the backside BEOL network by a backside S/D contact.

16. The semiconductor IC device of claim 10, further comprising:
a shallow trench isolation (STI) region underneath and between the first active region and the second active region and underneath the angled gate cut region.

17. The semiconductor IC device of claim 16, wherein a bottom surface of the angled gate cut region is substantially coplanar with a top surface of the STI region.

18. The semiconductor IC device of claim 12, wherein the frontside gate contact and the backside gate contact are located between the first active region and the second active region.

19. The semiconductor IC device of claim 12, wherein the frontside gate contact is a vertical interconnect access (VIA) contact within a frontside back end of line (BEOL) network and wherein the backside gate contact is a VIA contact within a backside BEOL network.

20. A method of fabricating a semiconductor integrated circuit (IC) device comprising:
forming a gate structure upon and around first channels of a first transistor and upon and around second channels of a second transistor;
forming an angled gate cut region opening within the gate structure separating the gate structure into a first gate upon and around the first channels of the first transistor and a second gate upon and around the second channels of the second transistor; and
forming an angled gate cut region by depositing dielectric material within the angled gate cut region opening.
